(19) United States
(12) Patent Application Publication
(10) Pub. No.: US 2026/0330108 A1
(43) Pub. Date: Oct. 22, 2026

(54) A COMPUTER-IMPLEMENTED METHOD FOR GENERATING & USING A HYDROGEN FUEL STATION ACCESS POLICY

(71) Applicant: VOLVO TRUCK CORPORATION, Göteborg (SE)

(72) Inventors: Parthav DESAI, Göteborg (SE); Jonas HELLGREN, Göteborg (SE)

(73) Assignee: VOLVO TRUCK CORPORATION, Göteborg (SE)

(21) Appl. No.: 19/103,432

(22) PCT Filed: Aug. 25, 2022
(86) PCT No.: PCT/EP2022/073712

§ 371 Date: Feb. 12, 2025

(51) Int. Cl. G06F 30/28; B60S 5/02; G07C 9/38

(52) U.S. Cl. CPC G06F 30/28; G07C 9/38; B60S 5/02

(57) ABSTRACT

A method includes providing a processor with an input dataset comprising a number of available fuel slots located at at least one fuel station, an expected time between two hydrogen vehicles requesting re-fueling, and priority-determining data for the at least one hydrogen vehicle requesting re-fueling. The method also includes the step of providing a processor with an access policy stored in a processor memory. The method further includes the step of carrying out a simulation to generate training data points, whereby each training data point expresses an action, input data, and a resulting short-term reward value, and using the generated training data points to perform access policy optimization using reinforcement learning to provide an access policy that is competent to determine, for a prescribed input, whether the at least one re-fueling request is to be accepted or rejected, based on a long-term value of accepting or rejecting a specific re-fueling request or a specific combination of re-fueling requests. The access policy optimization training is carried out when the processor is offline.

### TECHNICAL FIELD

The invention relates to a computer-implemented method for generating a hydrogen fuel station access policy. The present invention also relates to a method and system for managing at least one re-fuelling request from at least one hydrogen vehicle. Furthermore, the present invention relates to a computer program comprising program code means for performing the steps of one or more methods according to any of the embodiments of the invention when the computer program is run on a computer, and a computer readable medium carrying such a computer program.

### BACKGROUND

A hydrogen vehicle is a land, sea- or air-going vehicle that uses hydrogen fuel for motive power. The hydrogen vehicle generates power by converting the chemical energy of hydrogen to mechanical energy, either by reacting hydrogen with oxygen in a fuel cell to power an electric motor, or by burning hydrogen in an internal combustion engine.

Since hydrogen has a low volumetric energy density, it is usually stored onboard a vehicle as a compressed gas to achieve the desired driving range. Most current applications use high-pressure tanks to store the hydrogen. Currently, there are relatively few hydrogen fuel stations that can refill the hydrogen tanks of hydrogen vehicles with pressurized hydrogen. Since fuel stations are a scarce resource and will continue to be a scarce resource, access prioritization is needed to decide which hydrogen vehicles can get access to hydrogen. A hydrogen vehicle will not always be able to get access to hydrogen at a fuel station when it wants to have access.

US patent application no. US 2011/093305 discloses systems and methods that can be used to provide information to operators and managers of a hydrogen-based fleet of vehicles, notifying them of preferred or optimal times to refuel. The method comprises the steps of collecting data from each vehicle in the fleet of vehicles, collecting data from one or more hydrogen fuel stations available to the fleet, calculating a fuel benefit criterion or urgency for each vehicle in the fleet, such as the amount of hydrogen on-board each vehicle, identifying and ranking vehicles in the fleet according to the fuelling benefit criterion or urgency, and notifying vehicles in the fleet of re-fuelling opportunities according to ranking. An hydrogen fuel station access policy is thereby disclosed.

Example 11.1 on page 262 of the book entitled “Reinforcement Learning: An Introduction” discloses how an access policy may be generated using machine learning to train a processor memory while the processor memory is being used to control access in a real-world system, i.e. the processor memory is trained online. Customers of four different fixed priorities arrive at a single queue to obtain access to a number of servers. If given access to a server, the customers pay a reward of 1, 2, 4, or 8 units, depending on their priority, with higher priority customers paying more. In each time step, the customer at the head of the queue is either accepted (assigned to one of the servers) or rejected (removed from the queue). In either case, on the next time step the next customer in the queue is considered.

Reinforcement learning involves an agent, i.e., a set of states, and a set of actions per state. By performing an action, the agent transitions from state to state. Executing an action in a specific state provides the agent with a reward (a numerical score). The goal of the agent is to maximize its total reward. It does this by adding the maximum reward attainable from future states to the reward for achieving its current state, effectively influencing the current action by the potential future reward. For example, an accumulated reward is a weighted sum of expected values of the rewards of all future steps starting from the current state.

A system such as the system disclosed in example 11.1 on page 262 of the book entitled “Reinforcement Learning: An Introduction” can be very time-consuming to train. Furthermore, there may be a delay in giving or denying access to customers while a processor memory carries out a simulation step to apply the disclosed access policy.

### SUMMARY

An object of the invention is to provide an improved method for generating a hydrogen fuel station access policy to issue at least one action in response to at least one re-fuelling request from at least one hydrogen vehicle, whereby an action corresponds to either accepting a re-fuelling request and giving a hydrogen vehicle access to a fuel slot at a hydrogen fuel station or refusing such access.

According to a first aspect of the invention, which concerns the generation of such an access policy by training a processor memory using machine learning, the object is achieved by a computer-implemented method according to claim 1.

The method namely comprises the step of providing a processor, such as a central processor, with an input dataset comprising a number of available fuel slots located at at least one fuel station, an expected time between two hydrogen vehicles requesting re-fuelling, and priority-determining data for the at least one hydrogen vehicle requesting re-fuelling. The method also comprises the step of carrying out a simulation to generate training data points, whereby each training data point expresses an action, input data, and a resulting short-term reward value, whereby the short-term reward value may be a fuel station's income for a specific simulation step. The method further comprises the step of using the generated training data points to perform access policy optimization using reinforcement learning to provide an access policy that is competent to determine, for a prescribed input, whether the at least one re-fuelling request is to be accepted or rejected, whereby said access policy is configured to accept or reject one or more re-fuelling requests based on a long-term value of accepting or rejecting a specific re-fuelling request, or a specific combination of re-fuelling requests, The access policy optimization is carried out when the processor is offline, i.e. the processor memory is trained offline using reinforcement learning before the processor memory is used to generate an access policy to control fuel slot access in a real-world system, or when the processor memory is not being used to control fuel slot access in a real-world system to re-generate existing access policy.

As the offline training of the processor memory proceeds, the processor memory learns how to best react to incoming re-fuelling requests, and outputs optimal actions at each simulation step. When the trained processor memory is subsequently used in a real-world system or method to control fuel slot access, it merely needs to collect priority-determining data and data concerning the number of available fuel slots and carry out an automatic mapping to determine whether access to a fuel slot should be given or refused. This process can take a few nanoseconds. The combination of actions giving the highest long-term reward value, as regards the maximum revenue for one or more fuel stations for example, is selected when the trained processor memory is used in a real-world system or method.

The term “short-term reward” as used in this document is intended to mean the reward attained by accepting the at least one re-fuelling request from at least one hydrogen vehicle and giving one or more hydrogen vehicles access to one or more fuel slots at one or more hydrogen fuel stations over a relatively short period of time, such as the time between re-fuelling requests, a time period up to ten times the time between re-fuelling slots, or any other time period.

The term “long-term reward” as used in this document is intended to mean the accumulated reward attained by accepting said at least one re-fuelling request from at least one hydrogen vehicle and giving one or more hydrogen vehicles access to one or more fuel slots at one or more hydrogen fuel stations over a relatively longer period of time, such as a time period equal to or greater than ten times the time between re-fuelling requests. For example, the long-term reward may be the total revenue earned in one hour, or one day or one week, or one month or during any other period of time. Each time an action is taken, a certain reward is attained, or a certain amount of revenue is earned. The goal of the access policy is to maximize the accumulated reward, or the total amount of revenue earned over a certain (relatively long) period of time. This may be done by adding the maximum reward attainable from future states to the reward for achieving a current state, effectively influencing the current action by the potential future reward. For example, an accumulated reward is a weighted sum of expected values of the rewards of all future steps starting from the current state.

In a real-world system accepting a re-fuelling request from a hydrogen vehicle may be good in the short-term but bad in the long-term. For example, accepting a re-fuelling request from a hydrogen vehicle having a half-full hydrogen tank may be good in the short-term but bad in the long-term if it means that a subsequent re-fuelling request from a hydrogen vehicle having an almost empty hydrogen tank of the same size must be rejected due to a lack of available fuel slots.

According to an embodiment, online training of the processor memory may be carried out to refine the generated access policy in real time, but online training is not carried out to generate the access policy. The generation of the access policy is namely a primary training of the processor that is carried out offline. The optional subsequent training of the processor is carried online to refine the generated access policy, using real-world data for example.

An aim according to the first aspect of the invention is to generate an access policy in an improved manner. The generated access policy will maximize fuel station revenue and efficiency, maximize hydrogen availability and minimize hydrogen vehicle waiting times, when used in a real-world system and will thereby maximize service quality and minimize costs.

According to one embodiment the input dataset comprises data obtained from a real-world system, such as recorded data obtained from a real-world system, and/or data that simulates a real-world system. The amount of training data points may be selected based on a desired accuracy of the access policy optimization.

According to another embodiment the priority-determining data comprises: data concerning an amount of fuel onboard the at least one hydrogen vehicle requesting re-fuelling, data concerning a pre-payment of a fee, data concerning loyalty club membership, a request to use an additional service at a fuel station, such as to purchase parking or a meal, a time of day at which the at least one re-fuelling request is made. The term “priority-determining data” is intended to mean any data that allows a hydrogen vehicle's re-fuelling request to be prioritized over a re-fuelling request from one or more hydrogen vehicles.

According to one embodiment the expected time between two hydrogen vehicles requesting re-fuelling is derived using supervised learning. Supervised learning is the machine learning task of learning a function that maps an an input to an output based on example input-output pairs. It infers a function from labelled training data consisting of a set of training examples. In supervised learning, each example is a pair consisting of an input object (typically a vector) and a desired output value (also called the supervisory signal). A supervised learning algorithm analyzes the training data and produces an inferred function, which can be used for mapping new examples. An optimal scenario will allow for an algorithm to correctly determine the class labels for unseen instances. This requires the learning algorithm to generalize from the training data to unseen situations in a “reasonable” way.

According to an embodiment, the step of performing access policy optimization is carried out using a model-free reinforcement learning (Q-learning).

According to another embodiment, the step of performing access policy optimization is carried out using neural network-based reinforcement learning.

According to another embodiment the reward value is given by

R(x)=Σ_{ti=1 . . . T}revenue(ti)/T
where the term x represents the states in a system and is expressed by:

x={SoF₁, . . . ,SoF_{nSlots}},
and T is the time between re-fuelling requests from a distribution described by (m_{T},S_{T})
the revenue, i.e. a fuel station's income for a specific simulation step ti, is given by:

revenue(ti)=Σ_{i=1 . . . nSLots}\dot{m}(FLᵢ)·PH·dt(€)
where PH is the price of hydrogen (€/kg) and FL is priority-determining data, such as amount of fuel onboard the at least one hydrogen vehicle requesting re-fuelling, FLᵢ is the priority-determining data for hydrogen vehicle i, such as the fuel level of hydrogen vehicle i, and dt is a simulation time step (in seconds).

When the reward and transition functions are defined it is possible to apply Q-learning, whereby the term Q is a memory that indicates how good or bad it is to take a specific action. The term Q thereby expresses the long-term consequence of an action.

According to another embodiment, the method comprises the step of carrying out the step of performing access policy optimization before the processor is used in a real-world system, and/or during the use of the processor in a real-world system when the processor is offline.

According to a second aspect of the invention, which concerns the use of the generated access policy, the object of providing an improved method and system for managing at least one hydrogen re-fuelling request from at least one hydrogen vehicle, is achieved by a method according to claim 8 and a system according to claim 10.

The invention namely concerns a computer-implemented method that comprises the steps of: collecting data concerning a number of available fuel slots located at at least one fuel station, collecting input data including at least one re-fuelling request and priority-determining data from the at least one hydrogen vehicle, determining whether to accept or refuse the at least one re-fuelling request using an access policy that is configured to either accept a re-fuelling request and give a hydrogen vehicle access to a fuel slot located at a hydrogen fuel station, or refuse such access, which access policy is stored in a memory of a processor, notifying the at least one hydrogen vehicle of at least one fuelling opportunity, and generating the access policy using a method according to any of the embodiments described herein.

The method thereby provides a digital infrastructure for prioritizing the re-fuelling of hydrogen vehicles using a central processor. An advantage of this method is that the process of determining whether to accept or refuse the at least one re-fuelling request is very rapid since the processor memory does not need to carry out a simulation step to apply the generated access policy. The determining process can therefore take just a few nanoseconds.

According to an embodiment, the step of determining whether to accept or refuse the at least one re-fuelling request using the generated access policy comprises the step of carrying out an automatic mapping to determine whether access to a fuel slot should be given or refused.

The invention further relates to a system for managing at least one re-fuelling request from at least one hydrogen vehicle. The system comprises a wireless network, a central processor comprising a processor memory and an access policy stored in the processor memory and configured to either accept a re-fuelling request and give a hydrogen vehicle access to a fuel slot located at a hydrogen fuel station, or refuse such access. The central processor is configured to collect data concerning the number of available fuel slots located at the at least one fuel station, collect input data including at least one re-fuelling request and priority-determining data from the at least one hydrogen vehicle, determine whether to accept or refuse the at least one re-fuelling request using the access policy and notify the at least one hydrogen vehicle of at least one fuelling opportunity. The access policy is generated using a method according to any of the embodiments described herein.

An objective of such a system is to maximize the rewards that will be achieved following decisions regarding the numbers of re-fuelling requests that are accepted or rejected.

According to an embodiment, the priority-determining data comprises at least one of the following: data concerning the amount of fuel onboard (FL) the at least one hydrogen vehicle requesting re-fuelling, data concerning pre-payment of a fee, data concerning loyalty club membership, a request to use an additional service at a fuel station, such as to purchase parking or a meal.

According to another embodiment, said input dataset comprises at least one of the following: a time of day at which the at least one re-fuelling request is made, a time between two hydrogen vehicles requesting re-fuelling, a price of hydrogen, a fuelling rate.

According to further embodiment, the central processor is configured to record at least a part of the collected data. The recorded data may subsequently be used to generate an access policy a generated access policy.

According to a third aspect of the invention, which concerns the generation and/or the use of the access policy, the object is achieved by a computer program according to claim 14 and a computer readable medium carrying such a computer program according to claim 15.

The invention namely relates to a computer program comprising program code means for performing the steps of a method for generating a fuel station access policy according to any of the embodiments described herein and/or for performing the steps of a method for managing at least one hydrogen re-fuelling request from at least one hydrogen vehicle according to any of the embodiments described herein when the computer program is run on a computer.

Additionally, the invention relates to a computer readable medium carrying a computer program comprising program code means for performing the steps of a method for generating a fuel station access policy according to any of the embodiments described herein and/or for performing the steps of a for managing at least one hydrogen re-fuelling request from at least one hydrogen vehicle according to any of the embodiments described herein when the computer program is run on a computer.

Further advantages and advantageous features of the invention are disclosed in the following description and in the dependent claims.

### BRIEF DESCRIPTION OF THE DRAWINGS

With reference to the appended drawings, below follows a more detailed description of embodiments of the invention cited as examples.

In the drawings:

FIG. 1 shows a system for managing at least one re-fuelling request from at least one hydrogen vehicle according to an embodiment of the invention,

FIG. 2 shows a possible revenue-time relation after a decision to accept a re-fuelling request from a first hydrogen vehicle,

FIG. 3 shows a fuel rate function,

FIG. 4 shows update logic,

FIG. 5 shows an exemplary access policy, and

FIG. 6 is a flow chart showing the steps of a method for managing at least one re-fuelling request from at least one hydrogen vehicle according to an embodiment of the invention.

It should be noted that the drawings have not necessarily been drawn to scale and that the dimensions of certain features may have been exaggerated for the sake of clarity.

It should also be noted that any feature described with reference to a particular embodiment of a method, system, computer program or computer readable medium according to the invention, may be combined with the features of any other embodiment of the methods, system, computer program or computer readable medium according to the invention unless the description explicitly excludes such a combination.

### DETAILED DESCRIPTION OF EXAMPLE EMBODIMENTS OF THE INVENTION

FIG. 1 shows a system for managing at least one re-fuelling request from at least one hydrogen vehicle 10 according to an embodiment of the invention. A hydrogen vehicle 10 may be any type of a land, sea- or air-going vehicle that uses hydrogen fuel for motive power, such as a car, truck, bus, construction equipment vehicle, boat, submarine, aeroplane, or drone. The system comprises a wireless network and a central processor 12 comprising a access policy 14 that has been generated using a method according to the present invention and that is stored in a processor memory 16.

The central processor 12, which can be located at a fuel station 18 or any other suitable location, is configured to communicate with the at least one hydrogen vehicle 10 and at least one fuel station 18. The, or each fuel station 18 comprises a hydrogen supply 20, such as pressurized hydrogen stored in one or more tanks, at least one fuel slot 22.

It should be noted that a processor 12 and/or a processor memory 16 need not necessarily be constituted by a single unit but may comprise a plurality of processor and/or memory units located at the same location or at a plurality of locations.

The access policy 14 is configured to either accept a re-fuelling request from a hydrogen vehicle 10 and give that hydrogen vehicle 10 access to a fuel slot 22 located at a hydrogen fuel station 18, or refuse such access, depending on how the, or each hydrogen-vehicle requesting re-fuelling is prioritized.

The central processor 12 is configured to collect data concerning the number of available fuel slots 22 located at the at least one fuel station 18, collect input data including at least one re-fuelling request and priority-determining data from the at least one hydrogen vehicle 10, determine whether to accept or refuse the at least one re-fuelling request using the access policy 14, and notify the at least one hydrogen vehicle 10 of one or more fuelling opportunities at the at least one fuel station 18.

A hydrogen vehicle 10 namely submits a re-fuelling request to the central processor 12 either directly or indirectly via a fuel station 18 for example. The refuelling request can be accepted, whereby the requesting hydrogen vehicle 10 will be allowed to use a fuel slot 22 at a hydrogen refuel station 18 within a predefined time, or refuse the request, whereby the requesting hydrogen vehicle 10 needs to use another fuel station 18 or be placed in a queue slot.

A re-fuelling request can namely be rejected even if there is an available fuel slot 22 if the access policy 14 determines that it is necessary to have an available fuel slot for a more prioritized future incoming hydrogen 10 vehicle, such as a hydrogen vehicle 10 with a fuel level that is lower than the fuel level of a requesting hydrogen vehicle 10.

The objective of the access policy 14 is to transform a set of input signals of the input dataset to an action of either accepting or refusing the re-fuelling request. If the value of accepting a re-fuelling request is higher than the value of refusing the re-fuelling request, a requesting hydrogen vehicle 10 is given access to a fuel slot 22 at a fuel station 18.

The access policy 14 is generated by training a processor memory 16 offline using machine learning to emulate a real-world system. The generated access policy 14 may then be used in a real-world system to determine whether a hydrogen vehicle 10 requesting re-fuelling should be given access to an available fuel slot 22 depending on at least one priority-determining criterion, such as the amount of fuel on-board the hydrogen vehicle 10 requesting re-fuelling.

In order to generate the access policy 14, the central processor must be provided with an input dataset comprising the number of available fuel slots 22, nSlots, located at at least one fuel station 18, an expected time m_{T} between two hydrogen vehicles requesting re-fuelling, and priority-determining data, such as the normalized fuel level FL of the at least one requesting hydrogen vehicle 10. These terms may be included in a state s, i.e.

s{m_{T}nSlots,SoF}

This is called “feature selection” in machine learning.

Additionally, or alternatively, the access policy 14 can also be trained using the following priority-determining criteria: prepayment of a fee, a request to use an additional service at a fuel station, such as purchasing parking or a meal, and/or loyalty club membership.

The challenge is to train a processor memory to express the long-term value of a specific action taken in response to a specific state, more particularly, the long-term value of a specific action taken in response to a specific input s, or a specific combination of inputs, s, whereby an action means whether a fuel station shall acceptor refuse a re-fuelling request from a hydrogen vehicle.

The best action is obtained using a trained processor memory and will be the action that gives the highest value.

The term x={SoF₁, . . . , SoF_{nSlots}} expresses the states in the system. Every item in x corresponds, for example, to a fuel level of a hydrogen vehicle in a fuel slot. If an item is negative, the fuel slot is not used. So x={0.6,−1} means that a first fuel slot is taken by a hydrogen vehicle with SoF=60% and a second fuel slot is available, i.e. not being used.

A processor memory 12 may be trained using the following simulation environment.

An “infinite” queue of hydrogen vehicles 10 is considered to enter a fuel station 18 over a time period, T, drawn from a distribution expressed by (m_{T}, S_{T}), i.e., the expected value and standard deviation of time between re-fuelling requests.

At every event, i.e. the time stamp when a hydrogen vehicle enters a fuel station, a reward is calculated. The algorithm deriving the access policy is namely given the input data, s. After a simulation step, it is given the reward, R, the short-term value of accepting or not accepting a re-fuelling request.

The reward, R reflects the revenue the fuel station gets between the present time and until the following incoming hydrogen vehicle enters (or passes) the fuel station. The reward is expressed by

R(x)=Σ_{ti=1 . . . T}revenue(ti)/T(€/s)
where the term x represents the states in a system and is expressed by:

x={SoF₁, . . . ,SoF_{nSlots}},
and T is the time between re-fuelling requests from a distribution described by (m_{T},s_{T}), and the revenue, i.e. the fuel station income, for a specific simulation step, ti, is given by

revenue(ti)=Σ_{i=1 . . . nSLots}\dot{m}(FLᵢ)·PH·dt(€)
where PH is the price of hydrogen (€/kg) and FL is priority-determining data, such as the amount of fuel onboard the at least one hydrogen vehicle (10) requesting re-fuelling, FLᵢ is the priority-determining data for hydrogen vehicle i, such as the fuel level of hydrogen vehicle i, and dt is a simulation time step (in seconds),

The fuel rate for a specific slot with index i may be expressed as:

$$\dot{m} ( {FL}_{i} ) = \{ \begin{matrix}mDerMax \cdot ( 1 - {FL}_{i} ) + mDerMin \cdot ( {FL}_{i} ) & ( {FL}_{i} \geq 0 ) \\ 0 & ( else )\end{matrix} ( kg / s )$$

whereby said fuel level, SoF is updated according to FLᵢ←FLᵢ+\dot{m}(FLᵢ)/Cᵢ, where C is fuel capacity (kg),

If one considers the state x={0.6,−1}, the reward R(x) will be higher for accepting a re-fuelling request compared to refusing it, the reason being the available fuel slot.

If a following incoming second hydrogen vehicle has a lower FL, i.e. less than 60% fuel onboard, it would probably, in a long-term perspective, be better to reject the request of the first hydrogen vehicle and accept the following incoming second hydrogen vehicle instead. This is the core idea of the invention: to generate an access policy that makes good long-term decisions as regards maximizing the fuel station revenue. Maximizing the fuel station revenue implicitly maximizes hydrogen vehicle-driver satisfaction because high fuel station efficiency means high hydrogen availability.

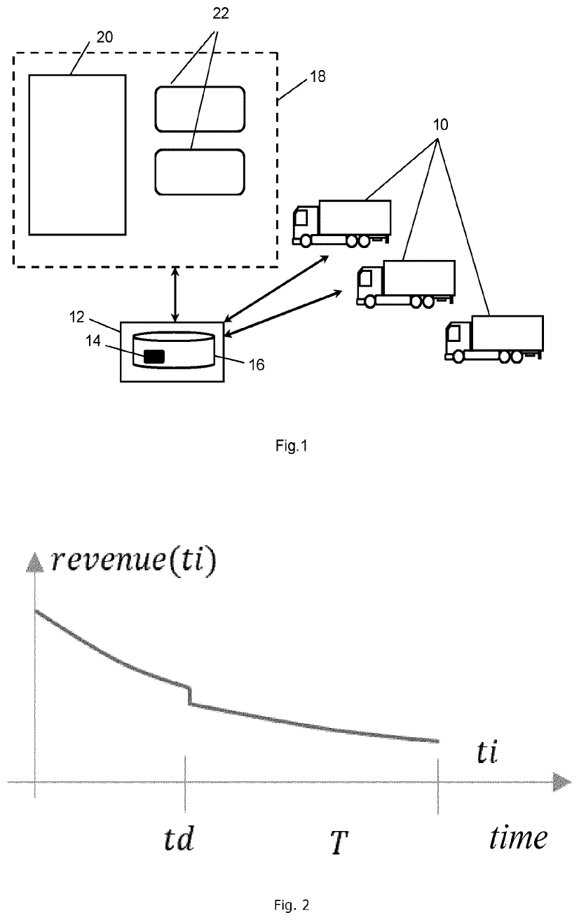

FIG. 2 shows a possible revenue-time relation after a decision to accept a re-fuelling request from the first hydrogen vehicle. The figure shows the revenue for every single time step between two hydrogen vehicles passing the fuel station. The drop in revenue is explained by the fact that the hydrogen vehicle already being re-fuelled has finished re-fueling at time td and hence leaves the fuel station.

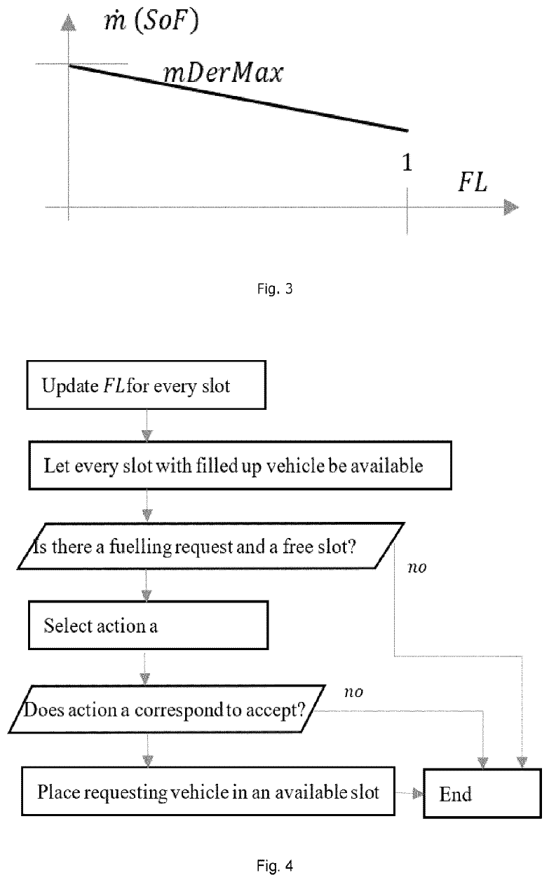

Conceptually, the fuel rate function should be as shown in FIG. 3. The more fuel that there is in a fuel tank of a hydrogen vehicle, the smaller the pressure difference relative the fuel tank. A small pressure difference means a small fuel rate. The consequence from this relationship is that a fuel station will earn more money per time unit servicing vehicles with a low fuel level. In practice this relationship might not be linear. It must however be decreasing to prioritize vehicles with a lower FL.

The term “mDerMax” is the maximum fuel rate. It is achieved when the fuel level of a hydrogen vehicle is zero. The term “mDerMin” is the minimum fuel rate. It is achieved when the fuel level of a hydrogen vehicle is 1, i.e. when the tank of a vehicle is completely full. From the fuel rate, the fuel level, SoF is updated according to:

FLᵢ←FL_{I}+\dot{m}(FLᵢ)/Cᵢ

In addition to the equation Error! Reference source not found. following logic is needed:
let filled up hydrogen vehicles leave the fuel station. Filled up vehicles have an FL equal to or larger than one. Fuel slots with such hydrogen vehicles will be defined as available, i.e. having a negative FL.
re-fuelling requests of hydrogen vehicles need to be handled. If there is an available fuel slot and the access policy accepts a re-fuelling request, the hydrogen vehicle will be placed in an available fuel slot.

The flow chart shown in FIG. 4 expresses this logic.

In cases with a large m_{T}, i.e. a long expected time between re-fuelling requests, the access policy is trivial and all re-fuelling requests may be accepted as there will always be available fuel slots.

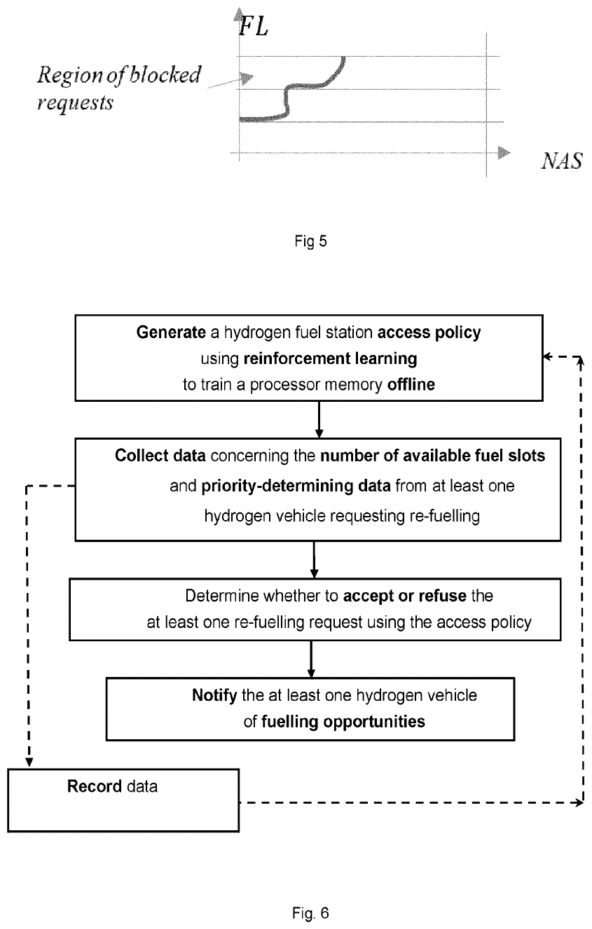

If m_{T} is moderate, i.e. of the same order of magnitude as the expected re-fuelling time, then a prioritization is needed. If there are few available fuel slots and a requesting hydrogen vehicle has a large FL, i.e. a large amount of fuel onboard, its re-fuelling request might be rejected. Such an access policy is illustrated FIG. 5.

It is evident that the expected time between fueling requests, m_{T} is important and needs to be known. According to an embodiment, m_{T} is derived using supervised learning. m_{T} may be a function of time. For example, m_{T} may be smaller during rush hours.

The access policy, q, is a function expressing the long-term value of taking action a in state s. It is the expected sum of reward and the value of being in the new state s′. This can be expressed mathematically as: q(s,a)=E[R+γ·V(s′)]

The new state s′ is given by a transition model, TM, whereby s′=TM(s,a)

One algorithm for deriving the access policy, or more generally the Q-function, is Q-learning. A Q-learning algorithm such as the following may be used in the methods described herein:

```
Initialize [symbol]  (s, a), ∀s ∈ [symbol]  , a ∈ [symbol] (s), arbitrarily, and [symbol]
(terminal-state, •) = 0
Repeat (for each episode):
  Initialize S
  Repeat (for each step of episode):
    Choose A from S using policy derived from [symbol]   (e.g., ϵ-greedy)
    Take action A, observe R, S′ [symbol]
    (S, A) ← [symbol]  (S, A) + α[R + γ maxₐ [symbol]  (S′,a) − [symbol]  (S, A)]
    S ← S′;
  until S is terminal
```

Once a fuel station access policy has been generated, it may be used in a real-world computer-implemented method or system for managing at least one hydrogen re-fuelling request from at least one hydrogen vehicle 10.

FIG. 6 is a flow chart showing the steps of a computer-implemented method for managing at least one hydrogen re-fuelling request from at least one hydrogen vehicle according to an embodiment of the invention,

Before the computer-implemented method is used to manage at least one hydrogen re-fuelling request from at least one hydrogen vehicle in a real-world system, a hydrogen fuel station access policy must be generated using a method described herein in which a reinforcement learning algorithm is used to train a processor memory.

When the generated access policy is subsequently being used in a real-world system, the computer-implemented method for managing at least one hydrogen re-fuelling request from at least one hydrogen comprises the step of collecting data concerning a number of available fuel slots located at at least one fuel station, and collecting priority-determining data from each hydrogen vehicle requesting re-fuelling, determining whether to accept or refuse the at least one re-fuelling request using the access policy, and notifying the at least one hydrogen vehicle of at least one fuelling opportunity at the at least one fuel station.

Optionally, the method comprises the step of recording at least part of the data that has been collected to use as an input dataset to regenerate the access policy being used in the method when the processor memory on which that access policy is stored is offline, or to generate another access policy.

Optionally, online training of the processor memory on which the access policy is stored may be carried out to refine the generated access policy in real time.

It is to be understood that the present invention is not limited to the embodiments described above and illustrated in the drawings; rather, the skilled person will recognize that many changes and modifications may be made within the scope of the appended claims.

1. A computer-implemented method for managing at least one hydrogen re-fueling request from at least one hydrogen vehicle, comprising the steps of:
collecting data concerning a number of available fuel slots (nSlots) located at at least one fuel station,
collecting input data including at least one re-fueling request and priority-determining data from said at least one hydrogen vehicle,
determining whether to accept or refuse said at least one re-fueling request using an access policy that is configured to be given the input data and either accept a re-fueling request and give a hydrogen vehicle access to a fuel slot located at a hydrogen fuel station, or refuse such access, which access policy is stored in a memory of a processor, and
notifying said at least one hydrogen vehicle of at least one fueling opportunity,
whereby said method comprises a further step of generating said access policy using a computer-implemented method for generating a fuel station access policy to issue at least one action in response to at least one re-fueling request from at least one hydrogen vehicle, whereby an action corresponds to either accepting a re-fueling request and giving a hydrogen vehicle access to a fuel slot at a hydrogen fuel station, or refusing such access, whereby said method for generating a fuel station access policy comprises the steps of:
providing a processor with an input dataset data set comprising the number of available fuel slots (nSlots) located at at least one fuel station, an expected time (m_{T}) between two hydrogen vehicles requesting re-fueling, and priority-determining data for said at least one hydrogen vehicle requesting re-fueling, and an access policy stored in a processor memory (16),
carrying out a simulation to generate training data points, whereby each training data point expresses an action, input data, and a resulting short-term reward value, and
using said generated training data points to perform access policy optimization using reinforcement learning to provide an access policy that is competent to determine, for a prescribed input, whether said at least one re-fueling request is to be accepted or rejected based on a long-term value of accepting or rejecting a specific re-fueling request or a specific combination of re-fueling requests, and whereby said access policy optimization training is carried out when said processor is offline such that access policy optimization is carried out before the processor memory is used to generate an access policy to control fuel slot access in a real-world system, or when the processor memory is not being used to control fuel slot access in a real-world system to re-generate existing access policy.

2. A method according to claim 1, whereby said input data set comprises data obtained from a real-world system, such as recorded data obtained from a real-world system, and/or data that simulates a real-world system.

3. A method according to claim 1, whereby said priority-determining data comprises at least one of the following: data concerning an amount of fuel onboard (FL) said at least one hydrogen vehicle requesting re-fueling, data concerning a pre-payment of a fee, data concerning loyalty club membership, a request to use an additional service at a fuel station, such as to purchase parking or a meal, a time of day at which said at least one re-fueling request is made.

4. A method according to claim 1, whereby said expected time (m_{T}) between two hydrogen vehicles requesting re-fueling is derived using supervised learning.

5. A method according to claim 1, whereby
said long-term reward value (R) is given by
R(x)=Σ_{ti=1 . . . T}revenue(ti)/T
where the term x represents the states in a system and is expressed by:
x={SoF₁, . . . ,SoF_{nSlots}},
and T is the time between re-fueling requests from a distribution described by (m_{T},s_{T})
the revenue, i.e. a fuel station's income for a specific simulation step ti, is given by:
revenue(ti)=Σ_{i=1 . . . nSLots}\dot{m}(FLᵢ)·PH·dt(€)
where PH is the price of hydrogen (€/kg) and FL is said priority-determining data, such as the amount of fuel onboard said at least one hydrogen vehicle requesting re-fueling, whereby FLᵢ is said priority-determining data for hydrogen vehicle i, such as the fuel level of hydrogen vehicle i, and dt is a simulation time step (in seconds).

6. A method according to claim 1, whereby said step of performing access policy optimization is carried out using a model-free reinforcement learning.

7. A method according to claim 1, whereby said step of performing access policy optimization is carried out using neural network-based reinforcement learning.

8. (canceled)

9. (canceled)

10. A method according to claim 1, whereby said step of determining whether to accept or refuse said at least one re-fueling request using said access policy comprises the step of carrying out an automatic mapping to determine whether access to a fuel slot should be given or refused.

11. A system for managing at least one re-fueling request from at least one hydrogen vehicle, comprising:
a wireless network; and
a central processor comprising a processor memory,
an access policy stored in said processor memory and configured to either accept a re-fueling request and give a hydrogen vehicle access to a fuel slot located at a hydrogen fuel station, or refuse such access,
whereby the central processor is configured to:
collect data concerning the number of available fuel slots (nSlots) located at said at least one fuel station,
collect input data including at least one re-fueling request and priority-determining data from said at least one hydrogen vehicle,
determine whether to accept or refuse said at least one re-fueling request using said access policy and said input data, and
notify said at least one hydrogen vehicle of at least one fueling opportunity, whereby said access policy is generated by said processor memory using a method
for generating a fuel station access policy to issue at least one action in response to at least one re-fueling request from at least one hydrogen vehicle, whereby an action corresponds to either accepting a re-fueling request and giving a hydrogen vehicle access to a fuel slot at a hydrogen fuel station, or refusing such access, whereby said method for generating a fuel station access policy comprises the steps of:
providing a processor with an input data set comprising the number of available fuel slots (nSlots) located at at least one fuel station, an expected time (m_{T}) between two hydrogen vehicles requesting re-fueling, and priority-determining data for said at least one hydrogen vehicle requesting re-fueling, and an access policy stored in a processor memory,
carrying out a simulation to generate training data points, whereby each training data point expresses an action, input data, and a resulting short-term reward value, and
using said generated training data points to perform access policy optimization using reinforcement learning to provide an access policy that is competent to determine, for a prescribed input, whether said at least one re-fueling request is to be accepted or rejected based on a long-term value of accepting or rejecting a specific re-fueling request or a specific combination of re-fueling requests, and whereby said access policy optimization training is carried out when said processor is offline such that access policy optimization is carried out before the processor memory is used to generate an access policy to control fuel slot access in a real-world system, or when the processor memory is not being used to control fuel slot access in a real-world system to re-generate existing access policy.

12. A system according to claim 11, whereby said priority-determining data comprises at least one of the following: data concerning an amount of fuel onboard (FL) said at least one hydrogen vehicle requesting re-fueling, data concerning pre-payment of a fee, data concerning loyalty club membership, a request to use an additional service at a fuel station.

13. A system according to claim 11, whereby said input data set comprises at least one of the following: a time of day at which said at least one re-fueling request is made, a time (m_{T}) between two hydrogen vehicles requesting re-fueling, a price of hydrogen, a fueling rate.

14. A system according to claim 11, whereby said central processor is configured to record at least a part of said collected data.

15. A computer program comprising program code means for performing the steps of a method according to claim 1 when said computer program is run on a computer.

16. A non-transitory computer readable medium carrying a computer program comprising program code for performing the steps of a method according to claim 1 when said computer program is run on a computer.
